(19) United States
(12) Patent Application Publication
(10) Pub. No.: US 2009/0084432 A1
(43) Pub. Date: Apr. 2, 2009

(54) Injection-molded housing of plastic for taking up electrical and/or electronic built-in components or installed devices

(76) Inventor: Ralf Kosmehl, Minden (DE)

Correspondence Address: SALTER & MICHAELSON;THE HERITAGE BUILDING, 321 SOUTH MAIN STREET, PROVIDENCE, RI, 029037128, US

(21) Appl. No.: 11/710,267

(22) Filed: Feb. 26, 2007

(30) Foreign Application Priority Data
Feb. 23, 2006 (DE) 10 2006 009 002.0

(51) Int. Cl. H01L 31/042; B29C 45/14

(52) U.S. Cl. 136/251; 264/328.1

(57) ABSTRACT

A molded housing that is injection-molded of plastic with outer-lying dimensionally stable walls for taking up electrical and/or electronic built-in components or installed devices, and the injection-molded housing provides a wall-integrated power generation in that the outer-lying stable walls serve, at least in partial regions, as a dimensionally stable support wall for flexible, thin-film solar cells.

### FIELD OF THE INVENTION

The invention relates to molded housings that are injection-molded of plastic with dimensionally stable walls for taking up electrical and/or electronic built-in components or installed devices.

### BACKGROUND OF THE INVENTION

Molded housings of the type named above are produced from a plastic with a hard surface that is insensitive to mechanical and chemical damage, such as, e.g., molded housings for cell phones or other molded housings for entertainment-type electronic devices. Also, technical housings, which serve, for example, in the industrial field for incorporating electrical and/or electronic functional units, must, with high reliability, protect the built-in components from mechanical damage and also, e.g., from oxidation. For this purpose, it is known to optimize and to simplify the installation of electrical and/or electronic components or devices in the molded housings by using the walls of the molded housings as protective units for electrical lines and by injection-molding the required electrical leads and derivative lines for the electrical power supply of the built-in components or installed device in the walls of the molded housing during the production of the plastic housing or by attaching them in the form of a flexible strip conductor on the inner surface of the walls of the molded housing (for reference, see: DE 196 09 253 C2 and EP 1 231 824 A2.

### SUMMARY OF THE INVENTION

The object of the present invention is to improve the electrical power supply for electrical and/or electronic components or devices, which are installed in such molded housings that are injection-molded from plastic.

The object is accomplished according to the invention in that the injection-molded housing itself, by means of a wall-integrated power generation, provides the power supply for the built-in components or installed devices, in that the outer-lying walls of the housing, at least in partial regions, serve as a dimensionally stable support wall for flexible, thin-film solar cells that are arranged on a foil and being electrically connected together in series, whereby the thin-film solar cells foils follow the respective shaping of the support walls over their entire surface and are mechanically or physically-chemically bonded with the support walls.

### DETAILED DESCRIPTION OF THE DRAWINGS

It should be understood that the drawings are provided for the purpose of illustration only and are not intended to define the limits of the disclosure. The foregoing and other objects and advantages of the embodiments described herein will become apparent with reference to the following detailed description when taken in conjunction with the accompanying drawings in which:

Embodiment examples of the invention will be described below on the basis of the drawings. Shown therein are the following:

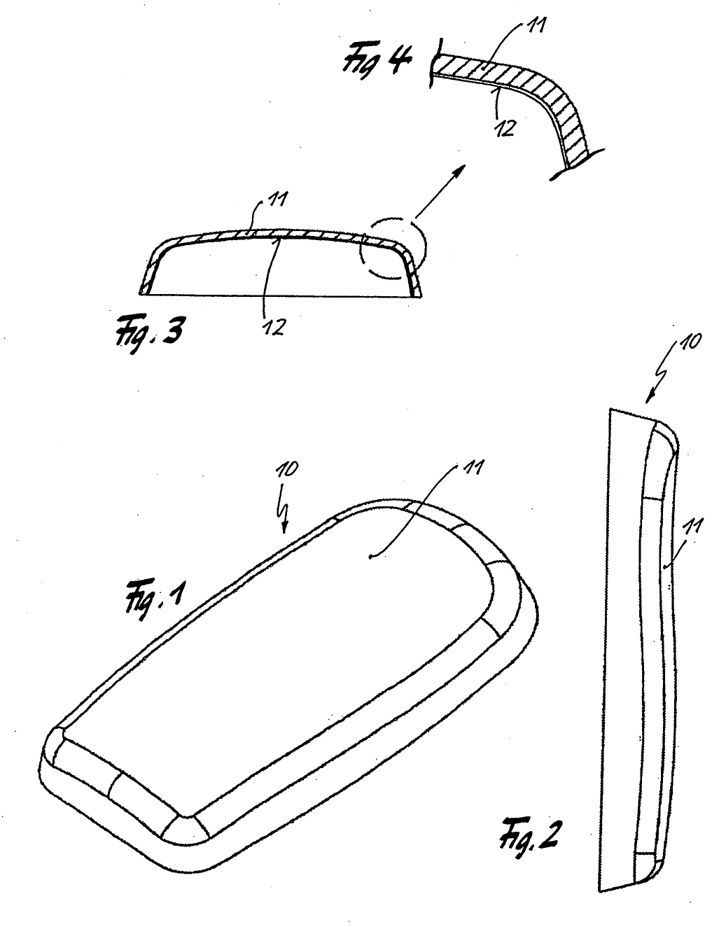

FIGS. 1 and 2 show a three-dimensional molded upper part 10 of a housing for cell phones. This upper part is produced from plastic by injection molding and has an outer-lying wall which serves as a dimensionally stable support wall 11 for a flexible thin-film solar cells foil 12.

The under part (not shown) of the housing can be of any other shape for taking up electrical and/or electronic build-in components (not shown).

The flexible thin-film solar cells arranged on the foil 12, which are electrically connected together in series, can be of any type that is known in the prior art. In general, two solar cells (also named photovoltaic cells) are connected in series by electrically connecting the anode of one cell with the cathode of the other cell.

FIGS. 3 and 4 show the thin-film solar cells foil 12 positioned on the inner surface of the support wall 11. The outer surface of the support wall is facing the user of the cell phone.

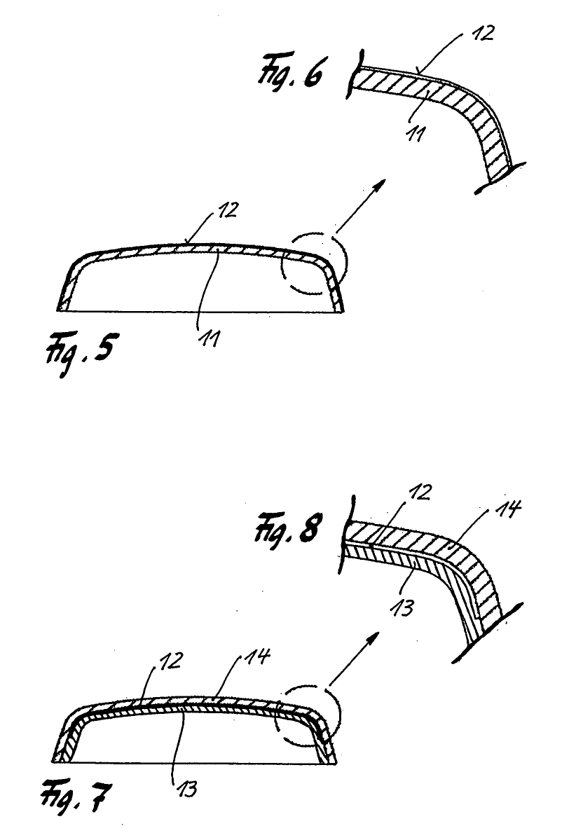

FIGS. 5 and 6 show an alternate embodiment in which the thin-film solar cells foil 12 is positioned on the outer surface of the support wall 11.

FIGS. 7 and 8 show still another embodiment in which the thin-film solar cells foil 12 is “sandwiched” between an inner wall 13 and an outer wall 14 of a double wall structure.

### DETAILED DESCRIPTION

A very cost-effective production process for an injection-molded housing according to the invention is possible, if, according to the present Application, the thin-film solar cells foils are positioned on the outer surface of the support walls, since in this case, the foils (usually a plastic or metal foil on which the thin-film solar cells are electro-deposited) can be inserted into the open plastic injection molding die and back-injected with plastic. When back-injected, electrical end contacts of the thin-film solar cells that have already been electrically connected together in series on the foil can be released, so that, starting from the inside space of the molded housing, an electrical connection between the thin-film solar cells and the built-in electrical and/or electronic components or devices can be produced without problem.

Alternatively, the electrical connections to the thin-film solar cells can also be produced by means of press pins, solder contacts, or clamp contacts accessible from the inside space of the molded housing.

The thin-film solar cells foils can be secured to the outer surface of the support walls by means of claw-type attachments arrested mechanically during the back-injection procedure. In other cases, the foil of the thin-film solar cells can be secured to the outer surface of the support walls in a physical-chemical manner by gluing.

In all of the above embodiments of the invention, in which the thin-film solar cells are positioned on the outer surface of the support walls, it is recommended to provide an additional protective foil or another light-transparent protective layer onto the thin-film solar cells foils, in order to avoid scratches or other undesirable mechanical damage of the thin-film solar cells.

Another embodiment of the invention is characterized in that the thin-film solar cells foils are positioned onto the inner surface of the support walls of the molded housing, wherein the support walls must be transparent to light in this region, at least within the wavelength range of light of operation.

Also, this embodiment follows the teaching of the invention, i.e., the dimensionally stable walls of the molded housing serve as a supporting structure for the flexible thin-film solar cells arranged on a foil. The flexible thin-film solar cells foils are applied all-over the inner surface of the support walls and follow their shaping in an unlimited manner. They are preferably glued in a physical-chemical manner to the inner surface of the support walls, whereby a light-transparent adhesive can be used, if necessary.

When the flexible thin-film solar cells foils are attached to the inner surface of the support walls, edge regions of the thin-film solar cells foils remain unattached, so that, due to their flexibility when the built-in components or installed devices are mounted into the molded housing, these edge regions can be guided to these and make possible a direct electrical connection to the built-in components or installed devices.

Another advantageous embodiment of the invention can be achieved in that the support walls are injection molded as a double wall structure. In a first shot, the outer wall of the support wall is injected-molded of a light-transparent plastic, after which the thin-film solar cells foils are introduced onto the inner surface of the outer wall and fixed in position, if necessary. Then the inner wall is injection-molded in a second shot, whereby regions of perforations in the foil of the thin-film solar cells can be “through-injected”, so that the thin-film solar cells foils are attached mechanically between the outer and inner walls of the support walls, and, as a consequence of being sandwiched between the two walls of the molded housing, they are very well protected against damage of all types.

1. An injection-molded housing of plastic with dimensionally stable walls for taking up electrical and/or electronic built-in components or installed devices:
is hereby characterized;
in that the injection-molded housing provides a wall-integrated power generation;
in that the outer-lying walls of the housing, at least in partial regions, serve as a dimensionally stable support wall for flexible thin-film solar cells arranged on a foil and electrically connected together in series;
wherein the thin-film solar cells foils follow the respective shaping of the support walls and are mechanically or physically-chemically bonded with the support walls.

2) The injection-molded housing according to claim 1,
further characterized
in that the thin-film solar cells foils are positioned on the outer surface of the support walls of the housing.

3) The injection-molded housing according to claim 1,
further characterized
in that the thin-film solar cells foils are positioned on the inner surface of the support walls of the housing facing;
and the support walls are transparent to light in these regions.

4) The injection-molded housing according to claim 1,
further characterized
in that the support walls of the molded housing are produced as a double wall structure, at least in the regions where the thin-film solar cells foils are disposed;
wherein the outer walls of the support walls are transparent to light;
and the thin-film solar cells foils are embedded between the outer and the inner walls of the support walls.

5) The injection-molded housing according to claim 1,
wherein the thin-film solar cells are electro-deposited on the foil and are inserted into an open plastic injection molding die and back-injected with plastic.

6) The injection-molded housing according to claim 5,
wherein when back injected, electrical end contacts of the thin-film solar cells that have been electrically connected together in series on the foil can be released, so that, starting from the inside space of the molded housing, an electrical connection between the thin-film solar cells and the built-in electrical and/or electronic components or devices can be produced.

7) The injection-molded housing according to claim 1,
Wherein the electrical connections to the thin-film solar cells are produced by means of press pins, solder contacts, or clamp contacts accessible from the inside space of the molded housing.

8) The injection-molded housing according to claim 2,
wherein an additional protective foil or another light-transparent protective layer is provided onto the thin-film solar cells foils.

9) The injection-molded housing according to claim 1,
wherein, when the flexible thin-film solar cells foils are attached to the inner surface of the support walls, edge regions of the thin-film solar cells foils remain unattached, so that, due to their flexibility when the built-in components or installed devices are mounted into the molded housing, these edge regions can be guided to these and make possible a direct electrical connection to the built-in components or installed devices.

10) A production process for an injection-molded housing comprising, providing thin-film solar cells foils that are positioned on the outer surface of the support walls of the housing providing foils with the thin-film solar cells electro-deposited on the foil so that it can be inserted into an open plastic injection molding die and back-injected with plastic.

11) The process according to claim 10,
wherein, when back injected, electrical end contacts of the thin-film solar cells that have been electrically connected together in series on the foil can be released, so that, starting from the inside space of the molded housing, an electrical connection between the thin-film solar cells and the built-in electrical and/or electronic components or devices can be produced.

12) The process according to claim 11,
wherein, in a first shot, the outer wall of the support wall is injection-molded of a light-transparent plastic, after which the thin-film solar cells foils are introduced onto the inner surface of the outer wall and fixed in position.

13) The process according to claim 12,
wherein then the inner wall is injection-molded in a second shot, whereby regions of perforations in the foils of the thin-film solar cells can be “through-injected”, so that the thin-film solar cells foils are attached mechanically between the outer and inner walls of the support walls of the molded housing, and, as a consequence of their positioning between the two walls of the molded housing, they are very well protected against damage of all types.
